(19) United States
(12) Patent Application Publication
(10) Pub. No.: US 2026/0173792 A1
(43) Pub. Date: Jun. 18, 2026

(54) METHOD FOR MANUFACTURING A BONDED WAFER STRUCTURE

(71) Applicant: Okmetic Oy, Vantaa (FI)

(72) Inventors: Erkki VESAPUISTO, Vantaa (FI); Jari MÄKINEN, Vantaa (FI)

(21) Appl. No.: 18/985,314

(22) Filed: Dec. 18, 2024

(51) Int. Cl. H01L 21/67; H01L 21/18; H01L 21/20

(52) U.S. Cl. CPC H10P 72/0428; H10P 10/128; H10P 90/1914

(57) ABSTRACT

The invention relates to a method for manufacturing a bonded wafer structure. The method comprises providing a top and a handle wafer structures, each comprising a hydrophilic bonding surface, obtaining waviness information of at least one of the bonding surfaces, adjusting at least one bonding process parameter to a predetermined value based on the waviness information, where adjusting of said bonding process parameter modifies the moisture bound to the at least one of the bonding surfaces, and bonding the top and handle wafer structures at the predetermined value of the bonding process parameter. The adjusting step may comprise adjusting the pressure in the bonding chamber to an intermediate pressure being in low vacuum range, and/or adjusting temperature of the top and/or handle wafer to an intermediate temperature higher than room temperature. The invention further relates to the bonded wafer structure obtained by said method.

### TECHNICAL FIELD

The invention relates to the field of semiconductor structure manufacture. In particular, the invention relates to a method for manufacturing a bonded wafer structure and a bonded wafer structure obtained by such method.

### BACKGROUND

In the field of semiconductor manufacturing, bonding techniques are crucial for creating multilayer or bonded wafer structures. Traditional bonding methods include direct bonding and fusion bonding, which involve bringing two wafer surfaces into close contact to initiate molecular adhesion. Bonding is usually performed in vacuum or air, and thus referred to as vacuum or air bonding respectively. These methods typically require the wafer surfaces to be extremely smooth and free from contaminants to ensure high bonding strength and minimal defects.

One issue with existing bonding techniques is the formation of voids at the bonding interface. Formation of voids rapidly increases when rougher wafer surfaces are used. Such voids pose significant reliability risks, especially in safety-critical applications, as they cause malfunction or failure of the devices.

Some known solutions focus on reduction of specific type of voids, such as edge voids. Such solutions are, however, still based on bonding wafers with highly smooth surfaces. Hence, there remains a need for a bonding method that can effectively optimise different types of voids across entire wafer without requiring excessively smooth surfaces.

### SUMMARY

An object of the present invention is to provide an alternative and improved method for manufacturing bonded wafer structures. One object of the present invention may be to provide a method for manufacturing bonded wafer structures with reduced or optimised number of voids, where the type of reduced or optimised voids is preferably at least small voids, or both small and medium voids, compared to vacuum bonding, without requiring excessively smooth surfaces. More particularly, instead of wafers with smooth surfaces, one object of the present invention may be to provide a method that enables a reduced number of voids, where the reduced voids are preferably at least small voids, more preferably small and medium voids, compared to vacuum bonding, when wafers with higher roughness, e.g., exhibiting waviness, are used. An object of the invention may thus be to facilitate bonding of imperfect wafers and increase the quality and reliability of bonded wafer structure manufacture. The characterizing features of the method according to the invention are given in claim 1. Another object of the invention is to provide an improved bonded wafer structure, the characterising features of which are given in the other independent claim.

According to a first aspect of the invention, the method for manufacturing a bonded wafer structure comprises a step of providing a top wafer structure comprising a top wafer and a first hydrophilic bonding surface, and a handle wafer structure comprising a handle wafer and a second hydrophilic bonding surface, wherein the wafer structures are provided into a bonding chamber.

A surface is considered hydrophilic if it attracts water, i.e., if it comprises hydroxyl groups (—OH sites) for water molecules to attach to. For example, a surface may be considered hydrophilic when the contact angle is less than 90 degrees. Hydrophobic may be considered as opposite to hydrophilic. For example, a silicon (Si) wafer treated by hydrofluoric acid (HF) does not have hydroxyl groups and is thus hydrophobic.

The method further comprises a step of obtaining waviness information of at least one of the bonding surfaces.

In this document, waviness term refers to the scale of surface roughness or imperfections spanning a range from upper end of microroughness range to lower end of nanotopography range. Waviness range may be described by lateral wavelength between 10-200 μm with surface height, or amplitude variations of less than 5 nm. Nanotopography range is considered to describe features with lateral wavelength between 0.2-20 mm and amplitude variations of 0-100 nm. Microroughness range is considered to describe features with lateral wavelength between 2 nm and 100 μm and amplitude variations of 0.1-1 nm. Waviness of a surface means that the surface comprises roughness or imperfections on the scale of waviness as defined above. The amount of waviness can be quantified relative to its scale, i.e. higher waviness means longer lateral wavelength and/or higher amplitude variations than lower waviness.

Obtaining waviness information of a surface may comprise, e.g., obtaining waviness information from a wafer specification sheet, estimating waviness, e.g., based on a manufacture method, or a measurement of the surface. Measurement of the surface may be performed by a surface metrology system, such as various profilometers, e.g., optical profilometers. Waviness information may comprise, e.g., the presence or lack of waviness, an indication of extent of waviness, such as low, medium, or high waviness, and/or a value or range quantifying the amount, density, lateral wavelengths, and/or vertical amplitude variations of the surface waviness.

The method further comprises a step of adjusting at least one bonding process parameter to a predetermined value to modify the moisture bound to the at least one of the bonding surfaces, wherein the predetermined value is based on the waviness information of the at least one of the bonding surfaces. Adjusting bonding parameter based on the waviness information so as to control moisture level at the bonding surfaces may facilitate bonding of imperfect wafers exhibiting waviness and result in high quality bonded wafer structures with reduced density of at least small voids, preferably small and medium voids, compared to vacuum bonding. The predetermined value may further depend on the bonded wafer structure requirements, such as if it is a safety critical component, in which case, the predetermined value may be optimized more accurately, for example by performing additional tests and/or obtaining more detailed waviness information.

The adjusting step comprises either adjusting the pressure in the bonding chamber as the at least one bonding process parameter to the predetermined value being an intermediate pressure, which is in low vacuum range or adjusting temperature of the top wafer and/or the handle wafer as the at least one bonding process parameter to the predetermined value being an intermediate temperature higher than room temperature. Low vacuum is defined here according to standard ISO 3529-1:2019 as a pressure from 1 mbar to atmospheric pressure. The intermediate pressure may instead be between 1 mbar and 500 mbar, or between 1 mbar and 200 mbar. The pressure in the bonding chamber may be reduced directly to the intermediate pressure.

The method further comprises a step of bonding the bonding surfaces of the top wafer structure and the handle wafer structure inside the bonding chamber with a non-negligible moisture content in gaseous form and the at least one bonding process parameter set to the predetermined value.

The method according to the invention may effectively reduce voids across entire wafer without requiring excessively smooth surfaces. In particular, the density of voids may be reduced compared to the conventional vacuum and air bonding when the bonded wafers exhibit significant waviness. More particularly, small and preferably also medium voids, may be reduced compared to vacuum bonding, whereas large, edge, and annealing voids may be reduced compared to air bonding. A void with a largest dimension, i.e. a diameter, of less than 100 μm is referred to as a small void. A void with a largest dimension, i.e., a diameter, of between 0.1-1.1 mm is referred to as a medium void. The effect of the waviness to the bonding quality and the tuning of the bonding process parameter to a specific range enables balancing and/or reducing formation of different types of voids. Bonding at intermediate pressure may improve cell yield, reduce variation and reduce voids associated with patterned supporting structures, so called anchors, of a cavity silicon on insulator wafer structures, further referred to as cavity SOI, such as C-SOI®, compared to conventional vacuum bonding method, significantly increasing the reliability of safety-critical components. The use of intermediate pressure may also reduce bow/warp variation from wafer to wafer compared to vacuum bonding

The step of providing the top and handle wafer structures may comprise providing an insulating layer on at least one surface of the top and/or handle wafer to form at least one of the bonding surfaces. The insulating layer may reduce parasitic capacitance, improve electrical isolation, reduce crosstalk and noise as well as power consumption due to minimized leakage currents. Moreover, the insulating layer may provide or improve the hydrophilicity of the bonding surface thus contributing to higher quality bonded wafer structures.

The insulating layer may be a silicon dioxide (SiO2) layer.

The top wafer may be Si.

The handle wafer may be Si, glass, sapphire, or ceramics.

The intermediate pressure may be chosen to be higher for the bonding surfaces exhibiting higher waviness than lower waviness, thus reducing the small and medium void, preferably at least small void, formation compared to lower pressure.

The step of providing the top and handle wafer structures may comprise selecting as top and handle wafer structures those with waviness of the respective bonding surfaces below a waviness threshold value or if one of said waviness's is substantially above the waviness threshold value, the other bonding surface is selected to have waviness substantially below the waviness threshold value. Such selection of wafers enables the use of higher waviness wafers while still obtaining high quality end product.

The method may further comprise a post-bonding inspection step to investigate presence of voids, especially presence of small voids, preferably also of medium voids, in the bonded wafer structure. The small and medium voids are particularly problematic in the end product, e.g. the bonded wafer structure, as they do not necessarily hinder the processing steps and are difficult to detect, but may nevertheless lead to device failure and hence pose a reliability issue, which is particularly important for safety-critical applications. The post-bonding inspection step may comprise investigating voids with scanning acoustic microscope (SAM). The post-bonding inspection step may be performed before and/or after the annealing step. Such post-bonding inspection may be particularly beneficial for quality assurance, which is crucial for safety critical components.

The bonding surfaces may be unpatterned or at least one of the bonding surfaces may comprise a pattern configured to form cavities when bonded to the other bonding surface. The current method is thus versatile and can be adapted to the specific properties of the provided wafers and the desired end product while optimizing the bonded wafer structure quality.

According to a second aspect of the invention, a bonded wafer structure is manufactured by the previously described method and comprises a top wafer structure having a first bonding surface bonded to a second bonding surface of a handle wafer structure, wherein the two bonding surfaces are hydrophilic surfaces, at least one of the bonding surfaces exhibits waviness.

### BRIEF DESCRIPTION OF THE FIGURES

Embodiments of the invention are described below in more detail with reference to the accompanying drawings, in which:

FIG. 1 shows a flowchart of the method for manufacturing a bonded wafer structure according to the invention,

FIG. 2 shows a two-dimensional view and an exploded two-dimensional view of the bonded wafer structure according to an embodiment of the invention,

FIG. 3 shows a flowchart of the method according to an embodiment of the invention where the dashed boxes indicate optional steps that may be included in various combinations to obtain different embodiments of the invention.

### DETAILED DESCRIPTION OF THE FIGURES

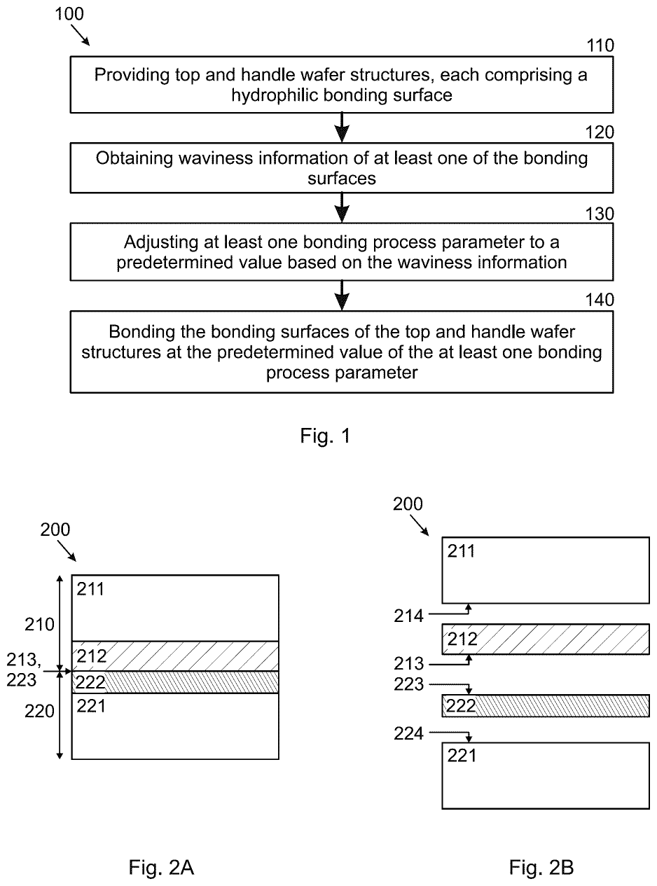

FIG. 1 illustrates an example of a method 100 for manufacturing a bonded wafer structure 200. An example of a resulting bonded wafer structure 200 is shown in FIG. 2A and as an exploded view in FIG. 2B.

The method comprises at least the steps of providing 110 top and handle wafer structures 210, 220, each comprising a hydrophilic bonding surface 213, 223, obtaining 120 waviness information of at least one of the bonding surfaces 213, 223, adjusting 130 at least one bonding process parameter to a predetermined value based on the obtained waviness information, and bonding 140 the bonding surfaces 213, 223 at the predetermined value of the at least one bonding process parameter.

The top wafer structure 210 comprises at least a top wafer 211 and a first hydrophilic bonding surface 213, whereas the handle wafer structure 220 comprises at least a handle wafer 221 and a second hydrophilic bonding surface 223 as shown in FIG. 2A, B. The hydrophilic bonding surfaces may be at an outer surface, i.e., exposed to the environment, of the corresponding wafer or the corresponding wafer structure. In this description, the bonding surface is considered to be the outer surface of a wafer or a wafer structure that is intended to be arranged to face a bonding surface of another wafer or wafer structure during bonding. In FIGS. 2A and 2B, the top wafer structure 210 is illustrated to comprise a layer 212 on a bottom surface 214 of the top wafer 211. The bottom surface of the top wafer is configured to face towards the handle wafer during the bonding step. The layer 212 may be an insulating layer, such as a native oxide layer or an insulating layer other than the naturally occurring native oxide, which is subsequently referred to as a processed insulating layer, or any other suitable layer that has a hydrophilic bonding surface 213. In principle, layer 212 is not necessary, if the bottom surface 214 is hydrophilic, in which case, the hydrophilic bonding surface 213 may be at the surface of the top wafer 211, and hence it may coincide with the bottom surface 214. Similarly, the handle wafer structure 220 is illustrated in FIG. 2A, B to comprise a layer 222 on a top surface 224 of the handle wafer 221. The top surface of the handle wafer is configured to face towards the top wafer during the bonding step. The layer 222, similarly, may be an insulating layer, such as a native oxide layer or a processed insulating layer, or any other suitable layer that has a hydrophilic bonding surface 223. In principle, layer 222 is not necessary, if the top surface 224 is hydrophilic, in which case, the hydrophilic bonding surface 223 may be at the surface of the handle wafer 221, and hence it may coincide with the top surface 224.

The bonding interface between the top wafer structure 210 and the handle wafer structure 220 is formed by the first and second bonding surfaces 213, 223. The first bonding surface may be a hydrophilic semiconductor surface 214, insulating layer 212 surface, such as semiconductor native oxide or processed insulating layer or other hydrophilic surface. The second bonding surface may be mutatis mutandis the same as the first bonding surface, or different, but selected from the same list. For example, the two bonding surfaces may be two native oxides, two processed insulating layers, such as thermal oxides, or one native oxide and one processed insulating layer.

The top wafer is preferably Si. However, other materials, such as indium tin oxide (ITO), sapphire (Al2O3), SiC, GaAs, Ge, InP, GaN or SiN could also be used, as long as they have or can be treated to provide a hydrophilic surface required by the current method. The treatment could include cleaning, etching, and/or deposition of layers, such as insulating layers.

The handle wafer is preferably Si, but ITO, Al2O3, SiC, GaAs, Ge, InP, GaN, SiN, glass or ceramics could also be used, if they have or can be treated to provide a hydrophilic surface. The treatment could include cleaning, etching, and/or deposition of layers, such as insulating layers. Different materials may be chosen based on application and needed properties, e.g., a glass handle wafer could be useful for transparency or specific thermal properties, sapphire for high temperature applications or for high electrical insulation, and ceramics for specific mechanical or thermal properties.

The top and handle wafers may, but do not have to, be made of the same material. Preferably, both wafers are made of Si, however, other combinations of materials provided above are possible. When both top and handle wafers are Si wafers, the bonded wafer structure may be referred to as bonded silicon on insulator (BSOI) or cavity silicon on insulator (cavity SOI).

A BSOI wafer structure is obtained by bonding two Si wafers together with an insulating layer between them. The two Si wafers may be unpatterned. Unpatterned may mean that the bonding surface of the wafer structure comprises height variations due to surface roughness without any additional manufactured features.

A cavity SOI wafer structure is obtained by bonding two Si wafers, where at least one of the wafers is patterned on the surface facing the other wafer. The patterning may be provided into the wafer surface and/or into an insulating layer provided on the wafer surface. Said patterning may be on the scale of few to hundreds of micrometres. Once the patterned wafer structure is bonded together with a second, patterned, or unpatterned, wafer structure, cavities between the two wafer structures are formed. A cavity SOI wafer structure can thus be referred to as a BSOI wafer structure that has built-in sealed cavities on the top and/or the handle wafer or on their respective wafer structures.

According to the method, the wafer structures 210, 220 are provided into a bonding chamber, preferably after obtaining 120 waviness information. According to the invention, the bonding chamber comprises a non-negligible moisture content in gaseous form at least during the bonding step 140. The bonding chamber may be kept at room temperature, although the bonding chamber temperature may also be set to a different value or vary during the method. The top and handle wafer structures may be washed, e.g. using water, and dried, e.g. by spin drying, before being inserted into the bonding chamber, however, the washing should not be performed on patterned wafer structures configured to form cavities when bonded with the other wafer structure to reduce the risk of contamination within the cavities.

The adjusting step 130 is specifically configured to modify the moisture bound to the at least one of the bonding surfaces 213, 223 by adjusting at least one bonding process parameter to a predetermined value. The at least one bonding process parameter may be, e.g., pressure in the bonding chamber, or temperature of the top wafer and/or the handle wafer. More than one bonding process parameter may be adjusted, such as both the pressure and temperature may be adjusted to corresponding predetermined values. The predetermined value for pressure as the bonding process parameter may be an intermediate pressure, which is in low vacuum range, whereas the predetermined value for temperature as the bonding process parameter may be an intermediate temperature higher than room temperature. According to the invention, the predetermined value is selected based on the obtained waviness information of the at least one of the bonding surfaces. Preferably, the predetermined value is selected based on the waviness information of both the first and the second bonding surfaces.

Preferably, the pressure in the bonding chamber is the at least one adjusted bonding process parameter. The pressure is thus adjusted 131 to the predetermined value, where the predetermined value is referred to as intermediate pressure. The intermediate pressure is in low vacuum range, i.e., between 1 mbar and atmospheric pressure. Preferably, the intermediate pressure is between 1 mbar and 500 mbar or 5 mbar and 500 mbar. More preferably, the intermediate pressure is between 1 mbar and 200 mbar. Depending on the starting wafer waviness and optionally on the specific final bonded wafer structure requirements, the intermediate pressure may be chosen to optimize the number of different type of voids forming at the bonding interface. For example, the intermediate pressure may be chosen to be higher for the bonding surfaces exhibiting higher waviness compared to wafers exhibiting lower waviness to reduce at least small voids, preferably also medium voids.

As discussed earlier, the method may be performed with wafer structures wherein at least one of the bonding surfaces comprises a pattern configured to form cavities when bonded to the other bonding surface. The bonded wafer structure in such case may be referred to as cavity SOI structure and lower intermediate pressures are preferred for manufacturing such cavity SOI structures than structures without cavities, at least since the pressure inside the cavities increases during any subsequent thermal treatment steps, such as annealing, and too high pressure in the cavities may lead into reduced quality and/or failure of the bonded wafer structure. The preferred intermediate pressures for the structures with cavities may be in the range between 1 mbar and 200 mbar, even more preferably between 1 mbar and 100 mbar.

When choosing the predetermined value of the bonding process parameter, it has been observed that while high water content on the bonding surfaces reduces at least small voids, preferably small and medium voids, by providing so called water bridges between the bonding surfaces thus enabling subsequent void closure, it tends to result in increased density of annealing voids, i.e. voids formed during annealing step since too high water content leads to formation of large amount of hydrogen gas at the bonding interface, expansion of which during annealing may break the bonding interface thus forming voids. When the bonding process parameter is pressure, high water content may be obtained by bonding at a high pressure, such as, e.g., above atmospheric pressure, which further is problematic as high pressure leads to air drag limiting the bonding wave speed and thus increasing density of large voids. In this disclosure, the term “bonding wave” refers to the molecular bonding or adhesion wavefront that propagates from the bonding initiation point over the bonding interface between the two wafers. The propagation of the bonding wave across the whole bonding surfaces of the two wafers thus enables bonding by molecular adhesion. Air bonding, i.e., at atmospheric pressure, may also lead to higher density of edge voids because of the sudden pressure drop at the wafer edge. Moreover, as mentioned earlier, bonding at high pressures may be undesirable for structures such as cavity SOI as the high pressure within the cavities may break the devices.

On the other hand, it has been observed that while low water content on the bonding surfaces reduces the problem with annealing voids, the bonded wafer structures are prone to at least small voids, usually also medium voids, due to the lack of water bridges for wafers exhibiting waviness. When the bonding process parameter is pressure, low water content may be obtained by vacuum bonding, such as at medium or high vacuum, which reduces air drag as well as pressure drop at the edge of the wafer, hence benefiting reduction of large and edge voids. Vacuum bonding of wafers exhibiting waviness and configured to form cavity SOI bonded structures is further prone to anchor voids in elements that can be detrimental for customer's components, especially in safety critical products.

An intermediate value is thus chosen for the predetermined value of the bonding process parameter to balance the probability and density of large, edge, and annealing voids as well as small, preferably also medium, voids. As the small voids, usually also medium voids, occur primarily due to presence of waviness on the surface, the predetermined value should be based on the waviness information of the bonding surfaces. Bonding at an intermediate pressure may thus avoid or at least reduce small and medium void, preferably at least small void, formation compared to vacuum bonding of a wafer exhibiting waviness by choosing a high enough pressure, while still limiting the risk of large voids, edge voids and annealing voids by choosing a low enough pressure and thus low enough water content. The intermediate pressure is also more suitable for bonded wafer structures comprising cavities. As higher waviness tends to lead to higher density of small and medium voids, a higher intermediate pressure may be chosen to reduce at least the small voids, preferably also medium voids. As a result, the current bonding method may be more adaptable and versatile relative to the surface quality, i.e., waviness, of the initial wafers, may enable improved bonding yield and enhanced reliability of the bonding interface compared to vacuum bonding, while avoiding the adverse effects caused by higher pressures such as air bonding.

Alternatively, or in addition, to the pressure in the bonding chamber as the adjusted bonding process parameter, temperature of the top and/or the handle wafer may be an adjusted bonding process parameter. The temperature may be adjusted 132 to the predetermined value, where the predetermined value is referred to as intermediate temperature, which is higher than room temperature. Similar to the pressure discussion, the intermediate temperature may be chosen to optimize the number of different types of voids at the bonding interface based on the waviness information and optionally on the final bonded wafer structure requirements. The temperature of the top and/or the handle wafer may be adjusted by preheating said wafer by a resistor and/or light.

At the bonding step 140, the bonding surfaces 213, 223 of the top and handle wafer structures 210, 220 are bonded inside the bonding chamber with the at least one bonding process parameter set to the predetermined value. During the bonding step, the moisture contained in the residual air in the bonding chamber binds to the hydrophilic bonding surfaces, which enables bonding of the wavy or rough bonding surfaces. The bonding may be direct bonding or fusion bonding. Preferably, the adjusting step 130 comprises adjusting the at least one bonding process parameter directly to the predetermined value, where adjusting of said bonding process parameter modifies the moisture bound to the at least one of the bonding surfaces. That is, preferably, adjustment is performed without intermediary steps, such as waiting at bonding process parameter values other than the predetermined value. If waiting steps at different values are present, preferably such value is at least between the starting value and the final, predetermined value at which bonding is performed.

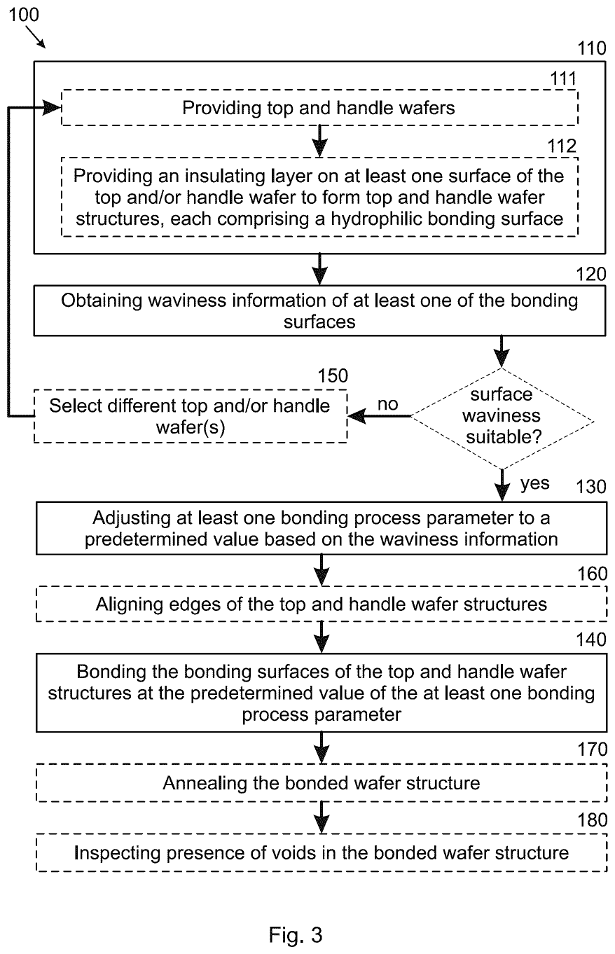

FIG. 3 illustrates the method 100 for manufacturing a bonded wafer structure further comprising multiple optional steps illustrated by dashed box boundaries. In one embodiment, the method 100 may comprise all the steps illustrated in FIG. 3. In other embodiments, the method 100 may comprise the steps marked with solid box boundaries and any combination of the optional steps. The order of method steps may be as shown in FIG. 1 and FIG. 3, however, it may also be different.

At step 110 of providing the top and handle wafer structures, FIG. 3 illustrates an example of sub-steps 111 and 112. The method 100 may thus comprise a step of providing 111 the top wafer 211 with the bottom surface 214 and the handle wafer 221 with the top surface 224. Furthermore, the method 100 may comprise a step of providing 112 the insulating layer 212, 222 on at least one surface of the top and/or handle wafer. The top wafer with the insulating layer may be referred to as the top wafer structure, and the handle wafer with the insulating layer may be referred to as the handle wafer structure. Note, however, that the insulating layer may be a native oxide and thus a wafer structure does not necessarily comprise a separately processed insulating layer. A wafer may refer to a wafer with or without a native oxide. Moreover, a wafer structure may also refer to the wafer alone. The top wafer structure and handle wafer structure terms are thus used to refer to the two parts of the bonded wafer structure that are to be bonded together during the manufacture method.

The insulating layer 212, 222 may be provided 112 on the top surface 224 of the handle wafer 221, on the bottom surface 214 of the top wafer 211 or on both of said surfaces. In case of other layers on the top and/or handle wafers that are not removed before provision of the insulating layer, the insulating layer 212, 222 may be provided 112 on at least one of the outer surfaces of the top and/or handle wafer structures facing the other wafer structure. If a wafer comprises a native oxide, such native oxide is preferably removed before providing the processed insulating layer. The provided insulating layer 212, 222 forms at least one of the bonding surfaces 213, 223.

The insulating layer may be a native oxide, or a processed insulating layer provided by treatment of wafer or wafer structure with oxygen plasma, UV, ozone, RCA cleaning, chemical oxidation, such as with piranha solution, thermal oxidation, spin coating, CVD, ALD or other methods. The insulating layer may improve the hydrophilicity of the bonding surface and thus lead to higher quality bonded wafer structure. Some of the treatment processes, such as treating with oxygen plasma or RCA cleaning, result in native-like oxide, however, as it might differ in properties due to different process in obtaining it, such layer is referred to as a processed insulating layer. Preferably, the insulating layer is a processed insulating layer, and more specifically a deposited or grown insulating layer, i.e., obtained by thermal oxidation, spin coating, CVD or ALD, which may further increase surface hydrophilicity and/or insulation and thus lead to higher bonded wafer quality. Instead, or in addition of providing an insulating layer, other treatments for increasing hydrophilicity of the surface may be provided to the wafer and/or wafer structure.

The insulating layer is preferably a silicon dioxide (SiO2) layer. The SiO2 layer is preferably provided by thermal oxidation, although other methods, such as CVD, PVD, spin coating, or ALD may also be used. The insulating layer could alternatively be silicon nitride (Si3N4) or sapphire (Al2O3).

The method 100 may further comprise selecting 150 as top and handle wafer structures those with waviness of the respective bonding surfaces below a waviness threshold value or if one of said waviness values is substantially above the waviness threshold value, the other bonding surface may be selected to have waviness value substantially below the waviness threshold value. In addition, or alternatively, a combined waviness threshold value may be defined, where a combined waviness value is based on the waviness of the bonding surface of the top wafer structure and bonding surface of the handle wafer structure. In such a case, the method 100 may comprise selecting 150 as top and handle wafer structures those with combined waviness value below the combined waviness threshold value. The waviness and/or combined waviness threshold value may depend on the product, i.e., bonded wafer structure, specification and thus may be defined differently for each case. The waviness and/or combined waviness threshold value may be defined to be a value where above the threshold, the waviness is so high that small voids are formed during bonding. For example, too steep structures may fail to bond, where too steep may be defined via a combination of lateral wavelength and amplitude parameters. The waviness threshold value could be a root mean square (rms) value of the waviness amplitude variation parameter set, for example, to 1 nm or lower, where the rms value may be measured by an optical measurement. Such selection may allow obtaining high quality bonded wafer structures for wafers with even higher waviness values. Such selection 150 may be performed once the waviness information is obtained. If the waviness information is obtained together with the provision of the wafers, the suitable wafers may be selected and paired immediately. If, however, the waviness information is obtained, e.g., measured, only after provision of an insulating layer to the wafer, a new wafer may need to be selected and the step 110 repeated as illustrated in FIG. 3.

Once the obtained waviness information of at least one of the bonding surfaces is satisfactory, the wafer structures may be placed into the bonding chamber and the adjusting step 130 may be performed as described earlier.

The method 100 may further comprise an alignment step 160, where the edges of the top and handle wafer structures are aligned.

The method 100 may further comprise an annealing step 170 after the bonding step 140 to strengthen the bond between the two wafer structures. During annealing the water in the water-bridge voids may be evaporated thus resulting in attachment, i.e., bonding of the bonding surfaces within the void. The annealing step is preferably performed at a temperature of at least 1000 C, preferably at least at 1100 C or at least at 1200 C. Annealing is typically performed in an atmospheric pressure, although different pressure may be present inside any voids and/or cavities within the bonded structure.

The method 100 may further comprise a post-bonding inspection step 180 to investigate presence of voids in the bonded wafer structure. Post-bonding means that the inspection step 180 is after the bonding 140 step. The post-bonding inspection step may comprise inspection before and/or after the annealing step 170. The inspection before the annealing step may comprise investigating voids with infrared (IR) inspection. The inspection after the annealing step may comprise investigating voids with scanning acoustic microscope (SAM). Preferably, the post-bonding inspection step 180 includes at least the inspection after the annealing step 170. Preferably, the investigated voids are at least small voids, more preferably both small and medium voids, where small voids are considered to be voids having a largest dimension, such as a diameter, below 100 μm and medium voids are considered to be voids having a largest dimension, such as a diameter, between 100 μm and 1.1 mm.

The bonded wafer structure 200, as shown in FIGS. 2A and 2B and discussed earlier is manufactured by the method 100 described earlier. It will be appreciated by a person skilled in the art that the invention is not limited to the embodiments described above but may vary within the scope of the appended claims. Considerations concerning the various embodiments of the method for manufacturing a bonded wafer structure may be flexibly applied to the embodiments of the bonded wafer structure mutatis mutandis and vice versa as would be appreciated by a skilled person. The bonded wafer structure 200 comprises at least a top wafer structure 210 having a first bonding surface 213 bonded to a second bonding surface 223 of a handle wafer structure 220. The bonding surfaces 213, 223 are hydrophilic surfaces, with at least one of the bonding surfaces exhibiting waviness. Preferably the bonded wafer structure 200 comprises at least one insulating layer 212, 222, more preferably two insulting layers as shown in FIG. 2A, B, between the top wafer and the handle wafer. Preferably, the at least one insulating layer is a processed insulating layer, i.e. a layer other than the native oxide. The bonded wafer structure 200 may comprise two native oxide layers, a native oxide and a processed insulating layer or two processed insulating layers between the top wafer and the handle wafer.

1. A method for manufacturing a bonded wafer structure, the method comprising at least the following steps of:
providing a top wafer structure comprising a top wafer and a first hydrophilic bonding surface, and a handle wafer structure comprising a handle wafer and a second hydrophilic bonding surface, wherein the wafer structures are provided into a bonding chamber,
obtaining waviness information of at least one of the bonding surfaces,
adjusting at least one bonding process parameter to a predetermined value to modify the moisture bound to the at least one of the bonding surfaces, wherein the predetermined value is based on the waviness information of the at least one of the bonding surfaces, and wherein said adjusting at least one bonding process parameter comprises
adjusting the pressure in the bonding chamber to the predetermined value being an intermediate pressure, which is in low vacuum range, or
adjusting temperature of the top wafer and/or the handle wafer to the predetermined value being an intermediate temperature higher than room temperature, and
bonding the bonding surfaces of the top wafer structure and the handle wafer structure inside the bonding chamber with a non-negligible moisture content in gaseous form and the at least one bonding process parameter set to the predetermined value.

2. The method according to claim 1, wherein the step of providing the top and handle wafer structures comprises providing an insulating layer on at least one surface of the top wafer and/or handle wafer to form at least one of the bonding surfaces.

3. The method according to claim 2, wherein the insulating layer is a silicon dioxide (SiO2) layer.

4. The method according to claim 1, wherein the top wafer is Si.

5. The method according to claim 1, wherein the handle wafer is Si, glass, sapphire, or ceramics.

6. The method according to claim 1, wherein when the adjusted bonding parameter is pressure, the intermediate pressure is between 1 mbar and 500 mbar.

7. The method according to claim 1, wherein when the adjusted bonding parameter is pressure, the pressure in the bonding chamber is reduced directly to the intermediate pressure.

8. The method according to claim 1, wherein the intermediate pressure is chosen to be higher for the bonding surfaces exhibiting higher waviness than lower waviness.

9. The method according to claim 1, wherein the step of providing the top and handle wafer structures comprises selecting as top and handle wafer structures those with waviness of the bonding surfaces below a waviness threshold value or if one of said waviness's is substantially above the waviness threshold value, the other bonding surface is selected to have waviness substantially below the waviness threshold value.

10. The method according to claim 1, further comprising a post-bonding inspection (180) to investigate presence of voids in the bonded wafer structure.

11. The method according to claim 1, wherein the bonding surfaces are unpatterned.

12. The method according to claim 1, wherein at least one of the bonding surfaces comprises a pattern configured to form cavities when bonded to the other bonding surface.

13. A bonded wafer structure manufactured by the method according to claim 1 comprising a top wafer structure having a first bonding surface bonded to a second bonding surface of a handle wafer structure, wherein the two bonding surfaces are hydrophilic surfaces, at least one of the bonding surfaces exhibiting waviness.
